(19) United States
(12) Patent Application Publication
(10) Pub. No.: US 2025/0072045 A1
(43) Pub. Date: Feb. 27, 2025

(54) LOW THRESHOLD HIGH DENSITY TRENCH MOSFET

(71) Applicant: Alpha and Omega Semiconductor International LP, Toronto (CA)

(72) Inventors: Sik Lui, Sunnyvale, CA (US); Madhur Bobde, Santa Clara, CA (US); Wenwen Li, Santa Clara, CA (US); Xiaobin Wang, San Jose, CA (US); Lingpeng Guan, San Jose, CA (US)

(21) Appl. No.: 18/455,611

(22) Filed: Aug. 24, 2023

(51) Int. Cl. H01L 29/78; H01L 29/06; H01L 29/66; H02J 7/00; H03K 17/0812

(52) U.S. Cl. CPC H01L 29/7813; H01L 29/0603; H01L 29/66734; H02J 7/00302; H02J 7/00306; H03K 17/08122

(57) ABSTRACT

A trench MOSFET device implements a trench source/body contact structure and includes a first MOSFET section and a second MOSFET section where the first MOSFET section has a body contact resistance lower than a body contact resistance of the second MOSFET section. In some embodiments, the first MOSFET section includes trench source/body contacts to make electrical contact with the source region and with a body contact doped region having a first doping level. In one embodiment, the second MOSFET section includes trench source/body contacts that contacts only the source region. In another embodiment, the second MOSFET section includes trench source/body contacts to make electrical contact with the source region and with a second body contact doped region having a second doping level lower than the first doping level. In some embodiments, the first MOSFET section has a transistor area much smaller than the transistor area of the second MOSFET section.

### FIELD OF THE INVENTION

The invention relates to semiconductor devices and, in particular, to trench MOSFET devices, such as MOSFET devices being applied for use as load switches.

### BACKGROUND OF THE INVENTION

Portable electronic devices are incorporating load switches to implement power management functions. In one application, load switches are applied in protection circuit modules, such as for a battery pack in a portable electronic device. In such an application, a protection circuit module or PCM includes one or more load switches and a protection control circuit operative to protect a battery from being overcharged or overdischarged, which can result in deterioration of the battery lifetime or catastrophic damage to the battery. The load switch is connected in series with a battery terminal and a terminal of the load, which can be another charger or an electronic device. The load switch is controlled by the protection control circuit to turn on to allow current to flow between the battery and the load. Alternately, the load switch is turned off to interrupt the charging or discharging of the battery.

A load switch is typically implemented using a switching device controlled by an on-off control signal. The switching device is typically a MOSFET (metal-oxide-semiconductor field-effect-transistor) device that passes current between the two current terminals, referred to as drain and source, in response to a control signal applied to the gate terminal. A load switch can be configured for high-side switching or low-side switching. Typically, a load switch is implemented as a PMOS transistor for high-side switching and as a NMOS transistor for low-side switching.

FIG. 1 illustrates an example of a protection control module incorporating a load switch. Referring to FIG. 1, a protection control module (PCM) 1 is implemented in a battery pack to protect a battery BT. The PCM 1 is therefore connected in parallel across the battery terminals P+ and P−. The battery terminals are to be connected to a load, which can be a charger or an electronic device. The PCM 1 includes a protection control circuit 2 supplied by the battery voltage and also monitoring the battery voltage. The protection control circuit 2 generates control signals to disconnect the battery from the load to prevent the battery BT from being overcharged or overdischarged. In the present example, the PCM 1 includes two load switches SW-D and SW-C connected in series between the negative terminal of the battery and the battery terminal P−. Load switch SW-D is switched off in response to the control signal from the protection control circuit 2 to prevent the battery from being overdischarged. Load switch SW-C is switched off in response to the control signal from the protection control circuit 2 to prevent the battery from being overcharged. In the present example, the load switches SW-D and SW-C are NMOS transistors configured for low-side switching.

In some examples, the load switches SW-D and SW-C are implemented as trench MOSFET devices. FIGS. 2(a) and 2(b) illustrate two exemplary embodiments of a trench MOSFET devices. Referring first to FIG. 2(a), a trench MOSFET device 3 is formed in a semiconductor layer 4. In the present example, the trench MOSFET device 3 is an NMOS MOSFET device and the semiconductor layer 4 is an N-type semiconductor layer and function as the drain of the MOSFET device. The MOSFET device 3 includes trench gates 6 formed in trenches that are formed in the semiconductor layer 4. Each trench gate 6 is isolated from the semiconductor layer 4 by a gate oxide layer 5. In the mesa adjacent to the trench gate structures, a body region 7 of P-type conductivity is formed in the semiconductor layer 4 and a source region 8 is formed in the body region at the top surface of the semiconductor layer and adjacent the trenches. The source region 8 is a heavily doped N+ region and is typically more heavily doped than the semiconductor layer 4.

Electrical connection to the drain of the MOSFET device 3 can be provided on the backside of the semiconductor layer 4. Electrical connection to the gate formed in the trenches can be provided in selected locations to electrically connect all of the trench gates. Electrical connection to the source and body of the MOSFET device 3 is made on the topside of the semiconductor layer 4, typically using a source/body contact that electrically connects both the source and the body regions. In the example shown in FIG. 2(a), a body contact doped region 9 is formed at the top surface of the body region and between the source regions 8 formed adjacent to the trenches. The body contact doped region 9 is a P-type doped region more heavily doped than the body region. A contact opening is made in an overlying isolation layer 11 to expose the source region 8 and the body contact doped region 9 and a conductive layer 10 is deposited into the contact opening to connect to both the source region and the body region. The conductive layer 10 is further patterned to form conductive lines to connect the source/body regions to a source electrode or to a source pad.

The trench MOSFET device 3 of FIG. 2(a) uses a surface or lateral source/body contact structure which requires large lateral silicon real estate to implement. In the interest of device size reduction, the trench MOSFET devices implementing trench or vertical source/body contact structures have been developed, as shown in FIG. 2(b). Referring to FIG. 2(b), in trench MOSFET device 12, the body contact doped region 9 is formed in the body region 7 under the N+source region 8. A trench contact opening is made in the overlaying isolation layer 11 and through the N+ source region 8 to reach the body contact doped region 9. A conductive layer 15, such as a tungsten plug, is deposited into the trench contact opening to make contact with the source region 8 on the sidewall and with the body contact doped region 9 at the bottom of the contact. A conductive layer 16, such as a metal layer, is formed on the isolation layer 11 to form conductive lines to connect the source/body regions to a source electrode or to a source pad.

By using a trench source/body contact structure, the lateral dimension of the MOSFET device can be reduced, enabling the size of the MOSFET device to be scaled down. However, scaling or shrinking of the MOSFET device using trench source/body contact structures may cause undesired secondary effect in transistor characteristics. For example, shrinking of the lateral dimension of the mesa between adjacent trench gate structures results in the body contact doped region 9 becoming increasingly closer in proximity to the channel region formed in the body region on the sidewall of the trenches, which may negatively impact device performance, such as by increasing the threshold voltage of the MOSFET device.

### SUMMARY OF THE INVENTION

According to one embodiment of the present invention, a trench MOSFET device having a first current terminal, a second current terminal and a gate terminal includes a trench gate structure formed in a trench in a semiconductor layer of a first conductivity type, the trench gate structure including a conductive gate layer formed in the trench and isolated from the semiconductor layer by a gate dielectric layer, the conductive gate layer forming the gate terminal; a body region of a second conductivity type in and at a first surface of the semiconductor layer adjacent the trench; a first doped region of the first conductivity type formed in the body region and at the first surface of the semiconductor layer adjacent the trench, the first doped region forming the first current terminal, wherein the semiconductor layer forms the second current terminal; and a first body contact doped region of the second conductivity type formed in a first portion of the body region and spaced apart from the first doped region and spaced apart from the trench, the first body contact doped region being more heavily doped than the body region. The trench MOSFET device includes a first MOSFET section formed in the first portion of the body region and a second MOSFET section formed outside of the first portion of the body region. The first MOSFET section has a body contact resistance lower than a body contact resistance of the second MOSFET section.

According to another embodiment of the present invention, a method for forming a trench MOSFET device includes providing a semiconductor layer of a first conductivity type; forming an array of trench transistor cells in the semiconductor layer, including forming the trench transistor cells being defined by trench gate structures; forming body regions of a second conductivity type in the array of trench transistor cells; forming source regions of the first conductivity type in the body regions of the array of trench transistor cells; forming a first body contact doped region of the second conductivity type in each body region in a first portion of the array of trench transistor cells, the first body contact doped region being spaced apart from the source region formed in the respective body region and spaced apart from the trench gate structure, the first body contact doped region being more heavily doped than the body region; forming a body contact to the first body contact doped region in the first portion of the body regions and to the source regions only outside of the first portion of the body regions; and forming a first conductive layer in contact with the body contact.

These and other advantages, aspects, and novel features of the present invention, as well as details of an illustrated embodiment thereof. will be more fully understood from the following description and drawings.

### BRIEF DESCRIPTION OF THE DRAWINGS

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily to scale.

FIG. 1 illustrates an example of a protection control module incorporating a load switch.

FIGS. 2(a) and 2(b) illustrate two exemplary embodiments of a trench MOSFET devices.

FIG. 3 is an equivalent circuit diagram of a trench MOSFET device in embodiments or the present invention.

FIGS. 4(a) and 4(b) are cross-sectional views of transistors cells in the trench MOSFET device in embodiments of the present invention.

FIG. 5 is a top view of the trench MOSFET device of the present invention illustrating a portion of the trench transistor array in some embodiments.

FIGS. 6(a) to 6(f) are cross-sectional views illustrating a fabrication process for forming the trench MOSFET device in embodiments of the present invention.

FIGS. 7(a) to 7(f) are perspective views illustrating the device structure during various processing steps in the fabrication process shown in FIGS. 6(a) to 6(f).

FIG. 8 is an equivalent circuit diagram of a trench MOSFET device in alternate embodiments or the present invention.

FIGS. 9(a) and 9(b) are cross-sectional views of transistors cells in the trench MOSFET device in embodiments of the present invention.

FIG. 10 is a top view of the trench MOSFET device of the present invention illustrating a portion of the trench transistor array in some embodiments.

FIGS. 11(a) to 11(f) are cross-sectional views illustrating a fabrication process for forming the trench MOSFET device in alternate embodiments of the present invention.

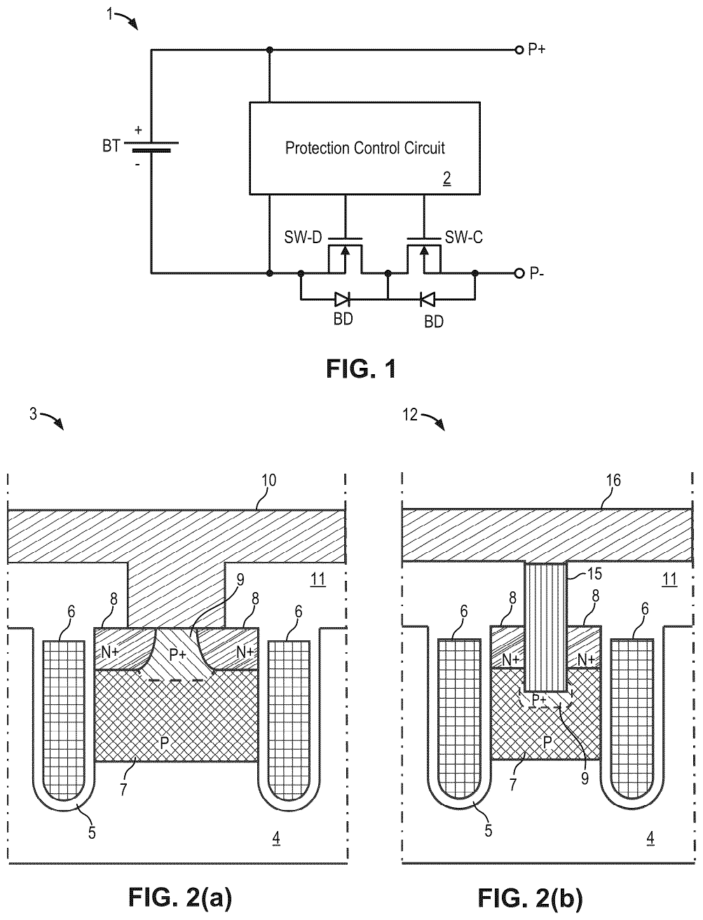

### DETAILED DESCRIPTION OF THE INVENTION

According to aspects of the present invention, a trench MOSFET device implements a trench source/body contact structure and includes a first MOSFET section and a second MOSFET section where the first MOSFET section has a body contact resistance lower than a body contact resistance of the second MOSFET section. In some embodiments, the first MOSFET section of the trench MOSFET device includes trench source/body contacts formed in the mesa between adjacent trench gate structures to make electrical contact with the source region and with a body contact doped region formed in the body region under the source region and having a first doping level. In one embodiment, the second MOSFET section of the trench MOSFET device includes trench source/body contacts that contacts only the source region. In another embodiment, the trench MOSFET device includes a second body contact doped region formed in the body region under the source region and having a second doping level more lightly doped than the first doping level. The second MOSFET section of the trench MOSFET device includes trench source/body contacts formed in the mesa between adjacent trench gate structures to make electrical contact with the source region and with the second body contact doped region. In some embodiments, the first MOSFET section has a transistor area much smaller than the transistor area of the second MOSFET section.

In some examples, the trench MOSFET device is applied to use as a load switch in a protection circuit module, such as a protection circuit module implemented in a battery pack to prevent overcharging or overdischarging of the battery. When applied as a load switch in a protection circuit module, a trench MOSFET device with certain electrical characteristics is sometimes desired.

First, it is often desirable for the trench MOSFET device to have a low on resistance. The on resistance of the trench MOSFET is the drain-to-source resistance when the MOSFET device is turned on, commonly referred to as Rds-on. To realize a low Rds-on resistance, a high density trench MOSFET device is needed. Trench MOSFET device is typically formed using an array of transistor cells defined by trench gate structures and the mesa in between. To realize a low Rds-on resistance, a high density array of transistor cells is desired. Meanwhile, to realize efficient use of silicon real estate, the trench MOSFET device implements trench source/body contact structures to reduce the die size for implementing a high density array of transistor cells.

Second, when applied as a load switch for protection circuit module applications, the load switch is only activated periodically. That is, there is no AC operation or the switch frequency is very low. Therefore, there is no particular capacitance requirement for the trench MOSFET device.

Third, when applied as a load switch for protection circuit module applications, the load switch is typically applied to switch a non-inductive load. Therefore, the requirement for the trench MOSFET device to have protection capability against inductive load switch-off, referred to as an Unclamped Inductive Switching (UIS) event, is also minimal. UIS capability is important for a MOS transistor device that is applied to switch an inductive load. When the MOS transistor switches off an inductive load in normal operation, the MOS transistor must absorb the energy stored in the inductive load. The over-voltage transient that occurs during inductive load switch-off is referred to as an UIS event. During a UIS event, the MOS transistor device is turned off but the drain and source junctions are in avalanche mode and conduct significant amount of current. Without any circuit protection, the parasitic bipolar transistor of the MOS transistor may turn on and irreversible damage to the transistor device may result. In this case, it is often desirable for the MOS transistor to have a low body contact resistance so that the parasitic bipolar transistor would not be turned on during an UIS event. In the case of a load switch in a protection circuit module application, the load switch is driving a non-inductive load and therefore the requirement for low body contact resistance can be relaxed.

Fourth, the load switch is typically configured for low-side switching and therefore the trench MOSFET device can be implemented using an N-channel or NMOS transistor device. Besides, NMOS transistors are suitable as NMOS transistors have lower drain-to-source resistance than PMOS transistors.

Lastly, when the load switch is applied in a protection circuit module for a battery pack, the battery voltage is low, such as between 3.0 to 3.8V, and therefore it is often desirable for the trench MOSFET device to have a low threshold voltage, such as less than 1.0V. For example, a threshold voltage of 0.6V or 0.7V is often desired for a trench MOSFET device applied as a load switch for a battery pack.

In embodiments of the present invention, a trench MOSFET device configured for use as a load switch in a protection circuit module. The trench MOSFET device is constructed using an array of trench transistor cells with trench gate structures and trench source/body contact structure to realize a high density transistor cell array for low on resistance Rds-on. Furthermore, the trench MOSFET device includes a portion of the trench gate transistor cells forming a first MOSFET section and another portion of the trench gate transistor cells forming a second MOSFET section. The first MOSFET section is formed with a first type of trench source/body contact structure and the second MOSFET section is formed with a second type of trench source/body contact structure. The first MOSFET section and the second MOSFET section are configured in a manner to optimize the body contact resistance as well as the threshold voltage of the trench MOSFET device. In particular, the first MOSFET section is configured with the first type of trench source/body contact structure to realize a lower body contact resistance than the second MOSFET section configured with the second type of trench source/body contact structure.

In some embodiments, the first type of trench source/body contact structure includes a heavily doped body contact doped region to realize a low body contact resistance, with the heavily doped body contact doped region possibly having a negative impact on the threshold voltage of the trench MOSFET device. Meanwhile, the second type of trench source/body contact structure may have no body contact doped region or only a lightly doped body contact doped region, which may result in a higher body contact resistance but without or with only minimal negative impact on the threshold voltage of the trench MOSFET device. In one example, for an N-type MOSFET device, the heavily doped body contact doped region, which is a P+ region, may cause an increase in the threshold voltage of the N-type MOSFET device by virtue of being in close physical proximity to the channel area of the NMOS transistor. By optimizing the transistor area of the first MOSFET section relative to the transistor area of the second MOSFET section, the trench MOSFET device can realize the desired low on resistance Rds-on and the desired threshold voltage value with acceptable body contact resistance for protection against transient over-voltage events. In some embodiments, the first MOSFET section has a transistor area much smaller than the transistor area of the second MOSFET section.

In embodiments of the present invention, the trench MOSFET device is used as a load switch in a protection circuit module, such as to connect to a battery back. The trench MOSFET device may be referred to as a switch circuit or a load switch circuit in some examples. It is understood that the trench MOSFET device of the present invention can have many applications and using the trench MOSFET device as a load switch for protection circuit module is one example application. In general, the trench MOSFET device has a first current terminal coupled to a first circuit node, a second current terminal coupled to a second circuit node, and a control or gate terminal coupled to receive a control signal for turning on or off the MOSFET device.

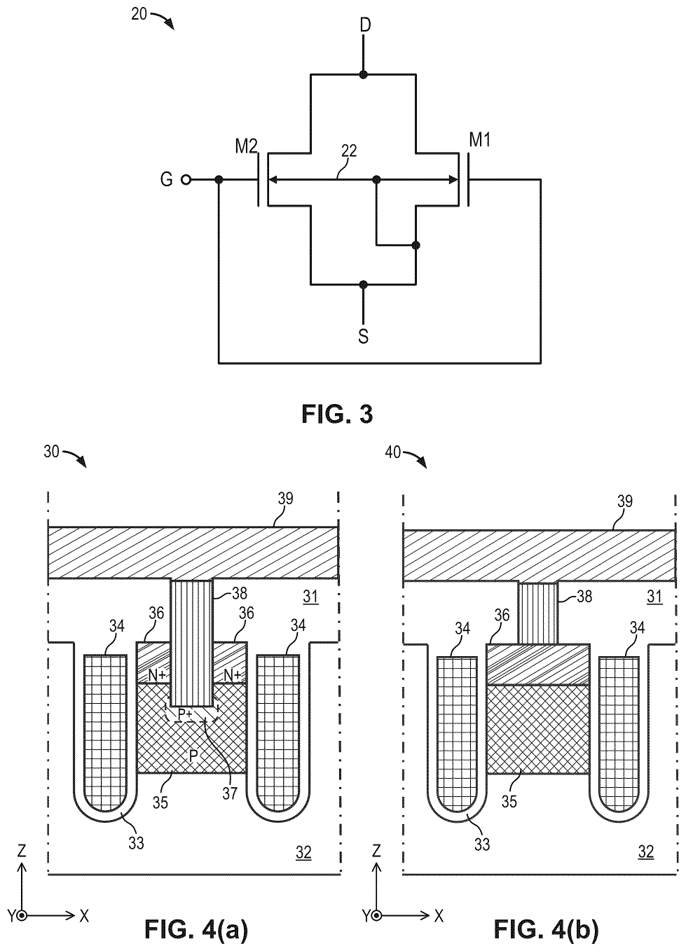

FIG. 3 is an equivalent circuit diagram of a trench MOSFET device in embodiments or the present invention. FIGS. 4(a) and 4(b) are cross-sectional views of transistors cells in the trench MOSFET device in embodiments of the present invention. In embodiments of the present invention, the trench MOSFET device is constructed as an N-type MOSFET device or an N-channel or NMOS transistor device. It is understood that a P-type MOSFET device or PMOS transistor device can be formed in the same manner by reversing the conductivity types of the device layers and doped regions. Referring first to FIG. 3, in embodiments of the present invention, a N-type trench MOSFET device 20 includes a first MOSFET section denoted as an NMOS transistor M1 and a second MOSFET section denoted as NMOS transistor M2. In construction, the first MOSFET section and the second MOSFET section are formed integrated as a monolithic MOSFET device. FIG. 3 is provided to illustrate the equivalent circuit diagram of the trench MOSFET device 20 including two transistor sections. The NMOS transistors M1 and M2, being part of the same trench MOSFET device 20, are connected in parallel. That is, the source terminals of NMOS transistors M1 and M2 are connected, the drain terminals of NMOS transistors M1 and M2 are connected, and the gate terminals of NMOS transistors M1 and M2 are connected.

To provide protection against transient over-voltage event, a low resistance contact to the body region of the trench MOSFET device is provided. In FIG. 3, the body contact of the trench MOSFET device 20 is denoted by a node 22. In the present embodiment, a low resistance body contact is formed in the NMOS transistor M1 with the body region being electrically connected to the source terminal. Meanwhile, the NMOS transistor M2 is not provided with any body contact. As thus constructed, the NMOS transistor M1 (first MOSFET section) has a lower body contact resistance than that of the NMOS transistor M2 (second MOSFET section). As thus constructed, the transistor area ratio of NMOS transistor M1 to NMOS transistor M2 is selected so that the trench MOSFET device has the desired on resistance Rds-on and desired threshold voltage with acceptable body contact resistance for transient over-voltage protection, that is, acceptable UIS protection capability. In some embodiments, NMOS transistor M1 has a transistor area much smaller than the transistor area of NMOS transistor M2.

In the present description, to facilitate reference to the figures, a Cartesian coordinate reference frame is used, in which the Z-direction is normal to the planar surface of the semiconductor layer and the X-direction and the Y-direction are orthogonal to the Z-direction and to each other, as indicated in the figures. In general, a trench in a semiconductor layer refers to a long and narrow channel made in the semiconductor layer. In the present embodiment, the trench for forming the trench gate structure has a length L that extends in a first direction (Y-direction) of the semiconductor layer and a width W that extends in a second direction (X-direction), orthogonal to and in the same plane as the first direction, of the semiconductor layer. The length L of the trenches is much larger than the width W of the trenches. In other words, the length of the trenches refers to the long dimension of the trenches and the width of the trenches refers to the narrow dimension of the trenches. Finally, the trenches has a depth in the third direction (Z-direction).

FIGS. 4(a) and 4(b) illustrate transistor cells for implementing the first MOSFET section and the second MOSFET section in the trench MOSFET device 20 of FIG. 3 in some embodiments. Referring to FIGS. 4(a) and 4(b), the trench MOSFET device 20 is formed in a semiconductor layer 32 and includes the first MOSFET section 30 (FIG. 4(a)) and the second MOSFET section 40 (FIG. 4(b)) formed in the semiconductor layer 32. In the present example, the trench MOSFET device 20 is an NMOS MOSFET device and the semiconductor layer 32 is an N-type semiconductor layer and functions as the drain of the MOSFET device. The trench MOSFET device 20 includes trench gate structures with trench gates 34 formed in trenches that are formed in the semiconductor layer 32. Each trench gate 34 is isolated from the semiconductor layer 32 by a gate dielectric layer 33. In some embodiments, the trench gate 34 is a polysilicon layer and the gate dielectric layer 33 is a silicon dioxide layer. In the mesa adjacent to the trench gate structures, a body region 35 of P-type conductivity is formed in the semiconductor layer 32 and a source region 36 is formed in the body region at the top surface of the semiconductor layer 32 and adjacent the trenches. The source region 36 is a heavily doped N+region and is typically more heavily doped than the semiconductor layer 32. The body region 35 is typically more heavily doped than the semiconductor layer 32 but more lightly doped than the source region 36. In operation, the channel of the NMOS transistor is formed in the portion of the body region 35 adjacent to the trench gate structure and between the source region 36 and the semiconductor layer 32. An isolation layer 31, such as a dielectric layer, is formed on the semiconductor layer 32 to insulate the structures formed therein. In some embodiments, the dielectric layer 31 may be a low-temperature silicon oxide layer (LTO) and/or a BPSG layer.

In embodiments of the present invention, electrical connection to the drain of the MOSFET device 20 can be provided on the backside of the semiconductor layer 32. Electrical connection to the trench gate 34 formed in the trenches can be provided in selected locations to electrically connect all of the trench gates. Electrical connection to the source and body of the trench MOSFET device 20 is provided on the topside of the semiconductor layer 32 using a source/body contact. In embodiments of the present invention, the trench MOSFET device 20 uses trench source/body contact structures to electrically connect the source and body regions or the source region alone. More specifically, in the first MOSFET section 30, a body contact doped region 37 is formed in the body region for enabling a low resistance connection to the body region. The body contact doped region 37 has the same conductivity type as the body region 35 and is more heavily doped than the body region 35. In the second MOSFET section 40, no body contact doped region is formed.

To form the trench source/body contact, trench contact openings are made in the isolation layer 31. In the first MOSFET section 30, the trench contact opening is further made through the N+ source region 36 to reach the body contact doped region 37. In the second MOSFET section 40, the trench contact opening is made only to the source region 36. A conductive layer 38, such as a tungsten plug, is deposited into the trench contact openings. In the first MOSFET section 30, the conductive layer 38 makes contact with the source region 36 on the sidewall and with the body contact doped region 37 at the bottom of the contact. In the second MOSFET section 40, the conductive layer 38 makes contact to the top surface of the source region 36 only. A conductive layer 39, such as a metal layer, is formed on the isolation layer 31 to form conductive lines to connect the source and body regions to a source electrode or to a source pad.

In this manner, the first MOSFET section 30 realizes low body contact resistance in the trench MOSFET device 20, even though at the risk of impacting the device characteristics of the trench MOSFET device 20, such as by causing an increase in the threshold voltage of the trench MOSFET device in that area. Meanwhile, the second MOSFET section 40 does not include the body contact doped region and therefore operates at the desired device characteristics of the trench MOSFET device 20, such as at the desired threshold voltage value. By selecting the appropriate transistor area ratio between the first MOSFET section 30 and the second MOSFET section 40, the trench MOSFET device 20 can be formed with the desired on-resistance Rds-on and the desired threshold voltage with acceptable body contact resistance.

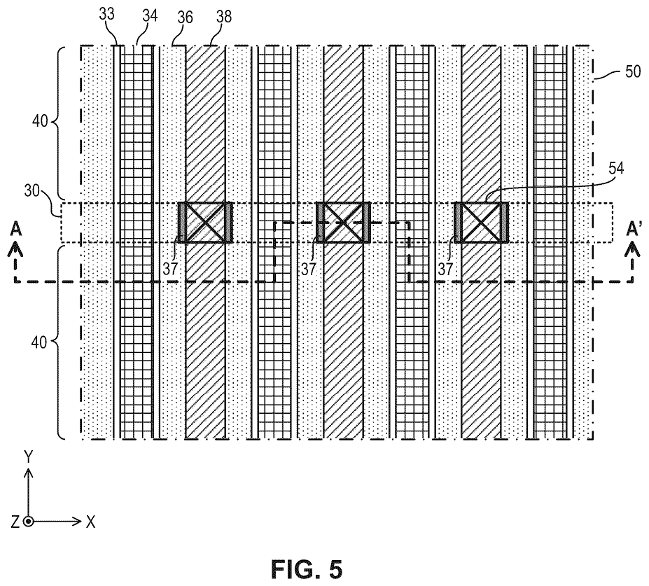

FIG. 5 is a top view of the trench MOSFET device of the present invention illustrating a portion of the trench transistor array in some embodiments. For example, FIG. 5 illustrates the trench MOSFET device 20 of FIGS. 3, 4(a) and 4(b) in some examples. Referring to FIG. 5, a portion 50 of the trench MOSFET device 20 includes the trench gate layer 34 and the gate dielectric layer 33 formed in parallel trenches in a cell array area of the semiconductor layer 32. The trench gate layer 34 in the parallel trenches are connected together, such as by additional trench gate portions, contact and metal layers. In the mesa between adjacent trench gate structures, the source region 36 (shown as dotted areas in FIG. 5) is formed in the body region 35 (not shown). Trench source/body contact 38 is formed above the source regions to contact the source region or the source and body regions.

The trench MOSFET device 20 includes the first MOSFET section 30 disposed in a given location along the Y-direction of the transistor cell array and the second MOSFET section 40 formed in the remaining cell array area. In particular, in the first MOSFET section 30, the body contact doped region 37 is formed in the body region 35 and the source/body contact 38 extends into the source region 36 to make contact with the body contact doped region 37, as denoted by the crossed-box 54. In the second MOSFET section 40, the source/body contact 38 only makes contact to the top surface of the source region 36. As shown in FIG. 5, the transistor area of the first MOSFET section 30 is smaller than the transistor area of the second MOSFET section 40. In some embodiments, the first MOSFET section 30 has a transistor area that is a fraction of the transistor area of the second MOSFET section 40. In one embodiment, the transistor area of the first MOSFET section 30 is between 5% to 25% of the transistor area of the second MOSFET section 40.

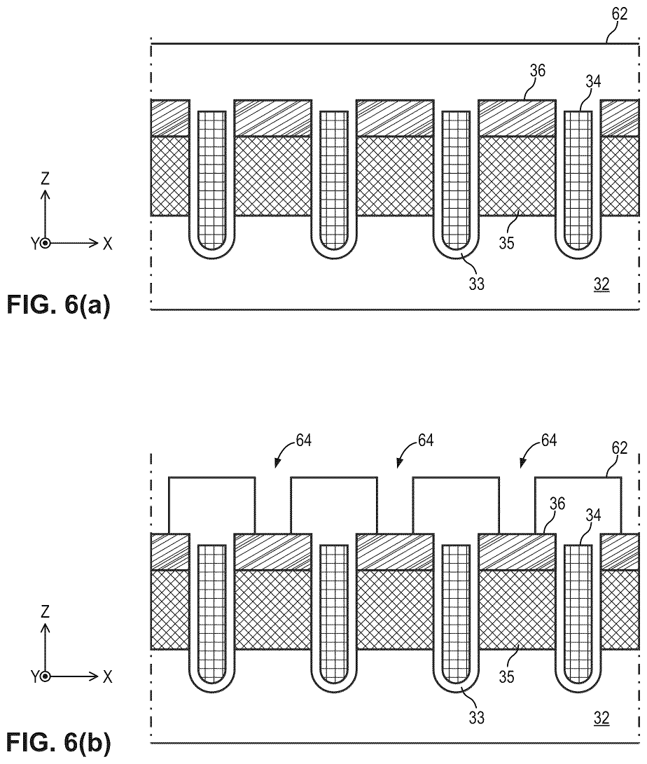

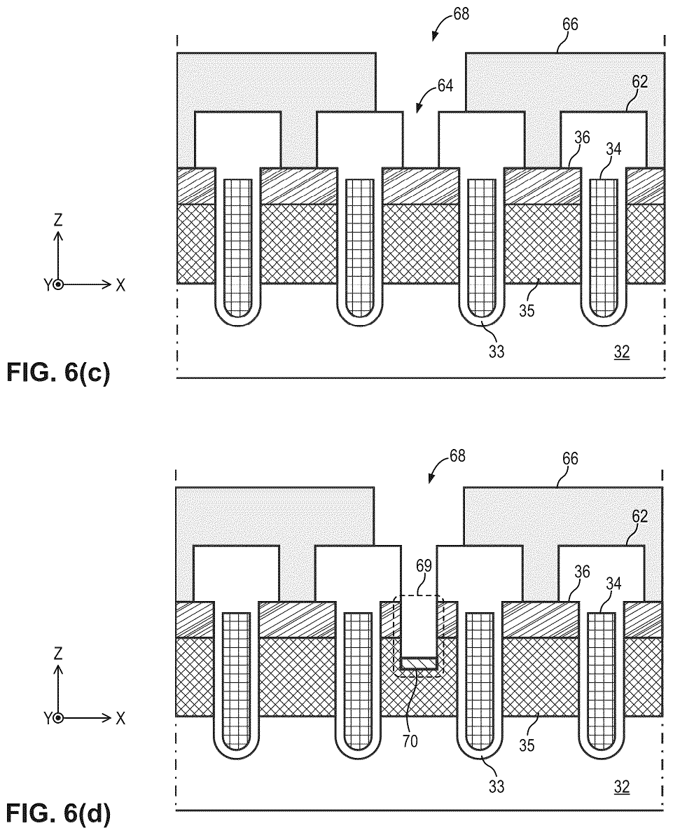

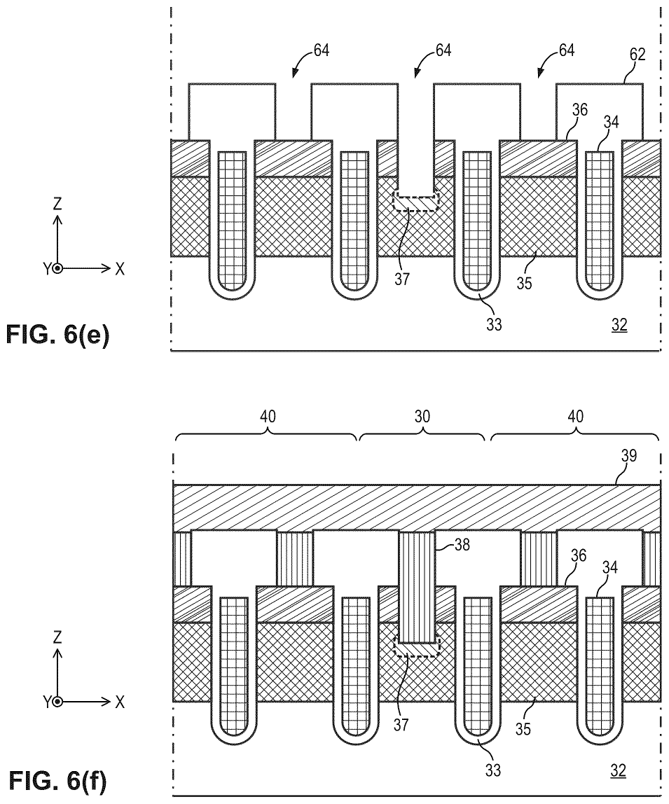

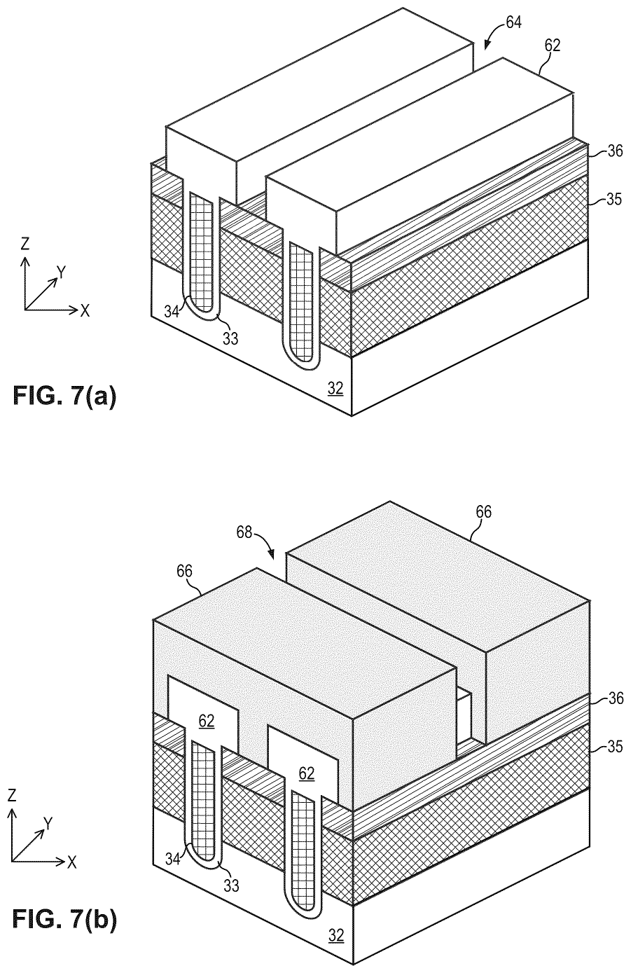

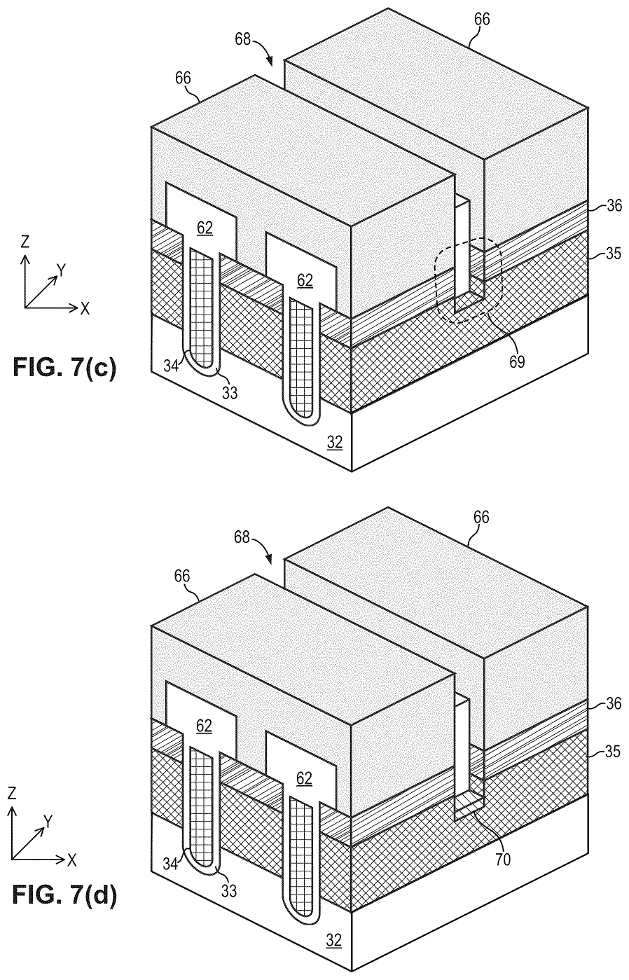

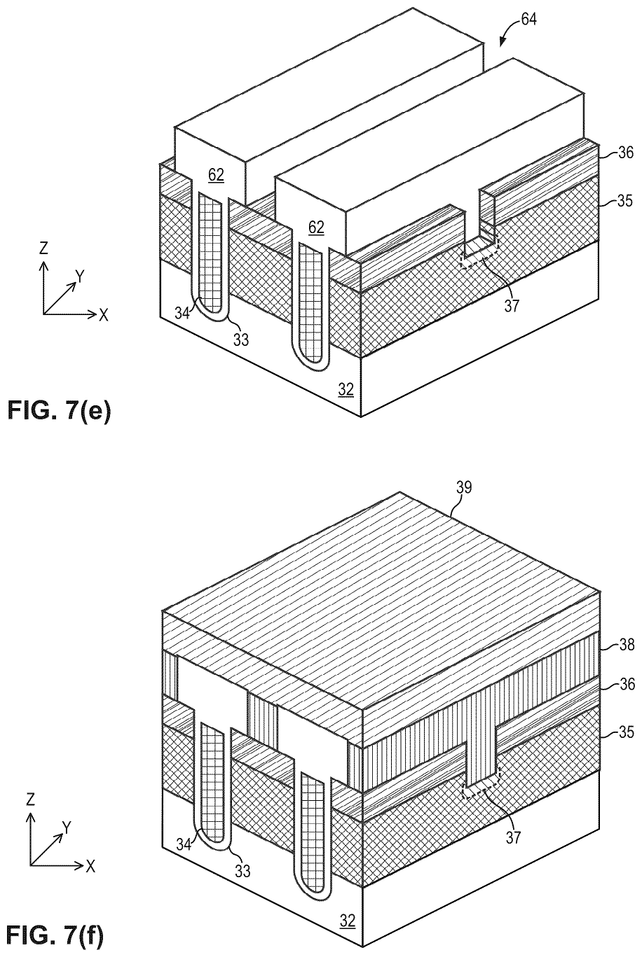

FIGS. 6(a) to 6(f) are cross-sectional views illustrating a fabrication process for forming the trench MOSFET device in embodiments of the present invention. FIGS. 7(a) to 7(f) are perspective views illustrating the device structure during various processing steps in the fabrication process shown in FIGS. 6(a) to 6(f). Like elements in FIGS. 3, 4(a), 4(b), 6(a) to 6(f) and 7(a) to 7(f) are given like reference numbers to simplify the discussion. Furthermore, in the following description, the cross-sectional views shown in FIGS. 6(a) to 6(f) are taken along the line A-A′ in FIG. 5 which traverses the first and second MOSFET sections 30, 40, which are spaced apart in the Y-direction. Taking the cross-sectional view along the line A-A′ allows the NMOS transistors formed in the first MOSFET section and the second MOSFET section to be viewed in the same cross-sectional views.

Referring to FIG. 6(a), the fabrication process starts with forming trenches in a cell array area of a semiconductor layer 32. In the present example, the trench MOSFET device 80 is an NMOS MOSFET device and the semiconductor layer 32 is an N-type semiconductor layer. A gate dielectric layer 33 is formed on the surface of the semiconductor layer 32 and in the trenches, for example, by either a chemical vapor deposition (CVD) process or by thermally grown. In one embodiment, the gate dielectric layer 33 is a silicon dioxide layer (SiO₂) and the gate dielectric layer 33 is also referred to as a gate oxide layer. A conductive gate layer 34 is then formed in the trenches. In some embodiments, the conductive gate layer 34 is a doped polysilicon layer. The doped polysilicon layer may be conformally deposited over the semiconductor layer 32 and the as-deposited doped polysilicon layer is etched back so that only the polysilicon layer in the trenches remains, forming the conductive gate layer 34. In some examples, the polysilicon layer can be deposited using a CVD process and etched back using a wet etch or a dry etch process. At this stage, the fabrication process has completed the trench gate structure formation for the trench MOSFET device. The fabrication process continues with applying the body implant to form the body region 35 in the mesa of the semiconductor layer 32 between the trench gate structures. For example, the body implant may be a lightly doped P-type implant. In one example, the body implant uses boron as the P-type dopant and has an implant dose of 2×10¹³/cm². A body anneal process for the body implant is performed to anneal and diffuse the implanted dopants, forming the body region 35. The anneal process may be performed in a non-reactive ambient at a high temperature, for example.

After the body anneal process, the fabrication process continues with applying the source implant to form the source region 36 in the mesa of the semiconductor layer 32 between the trench gate structures. For example, the source implant may be a heavily doped N-type implant. In one example, the source implant uses arsenic as the N-type dopant and has an implant dose of 1×10¹⁵/cm² to 5×10¹⁵/cm². A source anneal process for the source implant is performed to anneal and diffuse the implanted dopants, forming the source region 36 in the trench MOSFET device. The anneal process may be performed in a non-reactive ambient at a high temperature, for example. After the source anneal process, the trench MOSFET device is encapsulated by a dielectric layer 62. In the present embodiment, the dielectric layer 62 may be a low-temperature oxide layer (LTO) or a combination of LTO and a borophosphosilicate glass (BPSG) layer. The dielectric layer 62 can be deposited using CVD processes, for example. After the BPSG deposition, the semiconductor structure can be planarized, as shown in FIG. 6(a).

Referring to FIG. 6(b), a first contact mask (not shown) is applied to define openings to be made in the dielectric layer 62. A contact etch process, such as an anisotropic dry etch process, is then carried out using the contact mask to etch the dielectric layer 62 to form contact openings 64 to the source region 36. The resulting structure is also shown in FIG. 7(a). The contact openings 64 are formed exposing the source region 36 and the contact openings 64 extends in the Y-direction along the length of the trench gate structures.

Referring now to FIG. 6(c), a second contact mask 66 is applied to the semiconductor layer 32 over the dielectric layer 62. The second contact mask 66 defines locations at which the first MOSFET section is to be formed. In particular, the second contact mask 66 defines an opening 68 that extends in a X-direction, orthogonal to the direction of the contact openings 64 (Y-direction) made in the dielectric layer 62, as shown in FIG. 7(b). In this manner, the opening 68 (X-direction) is formed self-aligned to the contact openings 64 (Y-direction) of the dielectric layer 62. In particular, the opening 68 exposes a part of the contact openings 64 which in turn expose the source region 36.

Using the opening 68 defined by the second contact mask 66, which exposes a part of the openings 64 in the dielectric layer 62 that exposes the source region 36, the fabrication process etches the semiconductor layer 32 through the source region 36 and into the body region 35 to form a body contact opening, denoted by the dotted circle 69 as shown in FIGS. 6(d) and 7(c). A trench source/body contact is to be formed in the body contact opening denoted by dotted circle 69. A body contact implant 70 is applied using the second contact mask 66 to dope the bottom portion of the body contact opening 69, as shown in FIGS. 6(d) and 7(d). For example, the body contact implant 70 may be a high dose P-type implant. In one example, the body contact implant 70 uses boron or BF2 as the P-type dopant and has an implant dose of 8×10¹⁴/cm² to 1×10¹⁵/cm². The second contact mask 66 is then removed. An anneal process for the body contact implant is performed to anneal and diffuse the implanted dopants, forming the body contact doped region 37 in the trench MOSFET device, as shown in FIGS. 6(c) and 7(e). The anneal process may be performed in a non-reactive ambient at a high temperature, for example. In one example, the body contact doped region 37, as anneal, has a doping level of 5×10¹⁹/cm³ to 2×10²⁰/cm³ as compared to the doping level of the body region 35, having a doping level of 2×10¹⁷/cm³.

Subsequently, referring to FIGS. 6(f) and 7(f), tungsten plugs 38 are formed in the contact openings 64. For example, the tungsten plugs 38 may include a conductive adhesion layer, such as a titanium (Ti) or a titanium nitride (TiN) layer, and then a tungsten filler layer, both deposited by CVD or PVD processes. A conductive layer 39 is then deposited on the semiconductor structure. In one embodiment, the conductive layer 39 is an aluminum layer and may be deposited using a PVD process or evaporation. A metal mask may be applied and the conductive layer 39 is etched using the metal mask to form metal interconnects. At this stage, the fabrication process for forming the trench MOSFET device is completed.

As thus constructed, the tungsten plugs 38 made contact with the source region 36 and the body contact doped region 37 in the first MOSFET section 30 and the tungsten plugs 38 made contact with the source region 36 only in the second MOSFET section 40. In this manner, the NMOS transistor formed in the second MOSFET section 40 has a higher body contact resistance than that of the NMOS transistor formed in the first MOSFET section 30, which includes the body contact doped region 37. However, the device characteristics of the NMOS transistor in the second MOSFET section 40 may be better than those in the first MOSFET section 30, such as having a lower threshold voltage.

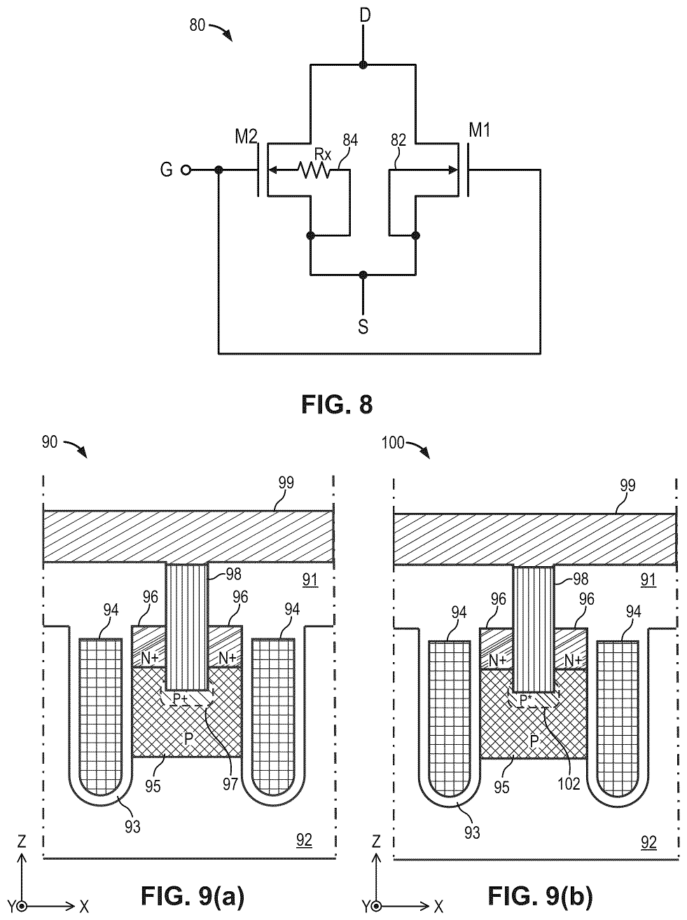

FIG. 8 is an equivalent circuit diagram of a trench MOSFET device in alternate embodiments or the present invention. FIGS. 9(a) and 9(b) are cross-sectional views of transistors cells in the trench MOSFET device in embodiments of the present invention. In embodiments of the present invention, the trench MOSFET device is constructed as an N-type MOSFET device or an N-channel or NMOS transistor device. Referring to FIG. 8, a N-type trench MOSFET device 80 is constructed in substantially the same manner as the trench MOSFET device 20 of FIG. 3, except with the provision of body contacts with high contact resistance in the second MOSFET section, denoted by NMOS transistor M2. More specifically, in trench MOSFET device 80, the first MOSFET section (NMOS transistor M1) has a body contact (node 82) to connect the body region to the source terminal. Meanwhile, the second MOSFET section (NMOS transistor M2) has a body contact (node 84) to connect the body region to the source terminal. The resistance of the body contact of the second MOSFET section (M2) is higher than the resistance of the body contact of the first MOSFET section (M1). The resistor Rx is used to denote the additional body resistance at the body contact of the second MOSFET section (M2).

FIGS. 9(a) and 9(b) illustrate transistor cells for implementing the first MOSFET section and the second MOSFET section in the trench MOSFET device 80 of FIG. 8 in some embodiments. Referring to FIGS. 9(a) and 9(b), the trench MOSFET device 80 is formed in a semiconductor layer 92 and includes the first MOSFET section 90 (FIG. 9(a)) and the second MOSFET section 100 (FIG. 9(b)) formed in the semiconductor layer 92. In the present example, the trench MOSFET device 80 is an NMOS MOSFET device and the semiconductor layer 92 is an N-type semiconductor layer and functions as the drain of the MOSFET device. The trench MOSFET device 80 includes trench gate structures with trench gates 94 formed in trenches that are formed in the semiconductor layer 92. Each trench gate 94 is isolated from the semiconductor layer 92 by a gate dielectric layer 93. In some embodiments, the trench gate 94 is a polysilicon layer and the gate dielectric layer 93 is a silicon dioxide layer. In the mesa adjacent to the trench gate structures, a body region 95 of P-type conductivity is formed in the semiconductor layer 92 and a source region 96 is formed in the body region at the top surface of the semiconductor layer 92 and adjacent the trenches. The source region 96 is a heavily doped N+ region and is typically more heavily doped than the semiconductor layer 92. The body region 95 is typically more heavily doped than the semiconductor layer 92 but more lightly doped than the source region 96. In operation, the channel of the NMOS transistor is formed in the portion of the body region 95 adjacent to the trench gate structure and between the source region 96 and the semiconductor layer 92. An isolation layer 91. such as a dielectric layer, is formed on the semiconductor layer 92 to insulate the structures formed therein. In some embodiments, the dielectric layer 91 may be a low-temperature silicon oxide layer (LTO) or a combination of LTO and a BPSG layer.

In embodiments of the present invention, electrical connection to the drain of the MOSFET device 80 can be provided on the backside of the semiconductor layer 92. Electrical connection to the trench gate 94 formed in the trenches can be provided in selected locations to electrically connect all of the trench gates. Electrical connection to the source and body of the trench MOSFET device 90 is provided on the topside of the semiconductor layer 92 using a source/body contact. In embodiments of the present invention, the trench MOSFET device 90 uses trench source/body contact structures to electrically connect the source and body regions.

More specifically, in the first MOSFET section 90, a body contact doped region 97 is formed in the body region 95 for enabling a low resistance connection to the body region. The body contact doped region 97 has the same conductivity type as the body region 95 and has a first doping level that is more heavily doped than the body region 95. In the second MOSFET section 100, a body contact doped region 102 is formed in the body region 95 for providing a connection to the body region. The body contact doped region 102 has the same conductivity type as the body region 95 and has a second doping level that is more heavily doped than the body region 95 but more lightly doped than the body contact doped region 97. Accordingly, by providing the body contact doped region 97 being more heavily doped than the body contact doped region 102, the first MOSFET section 90 has a body contact resistance that is lower than the body contact resistance of the second MOSFET section 100.

To form the trench source/body contact, trench contact openings are made in the isolation layer 91 and through the N+ source region 96 to reach the respective body contact doped region 97 or 102. A conductive layer 98, such as a tungsten plug, is deposited into the trench contact openings. In the first MOSFET section 90, the conductive layer 98 makes contact with the source region 96 on the sidewall and with the body contact doped region 97 at the bottom of the contact. In the second MOSFET section 100, the conductive layer 98 makes contact with the source region 96 on the sidewall and with the body contact doped region 102 at the bottom of the contact. A conductive layer 99, such as a metal layer, is formed on the isolation layer 91 to form conductive lines to connect the source and body regions to a source electrode or to a source pad.

In this manner, the trench MOSFET device 80 is provided with acceptable body contact resistance for protection against transient events. In particular, the first MOSFET section 90 is provided with a low body contact resistance in the trench MOSFET device 80 while the second MOSFET section 100 is provided with a higher body contact resistance than the first MOSFET section 90. By using a more lightly doped body contact doped region 102, the negative impact to the device characteristics of the trench MOSFET is mitigated. By selecting the appropriate transistor area ratio between the first MOSFET section 90 and the second MOSFET section 100, the trench MOSFET device 80 can be formed with the desired on-resistance Rds-on and the desired threshold voltage with acceptable body contact resistance.

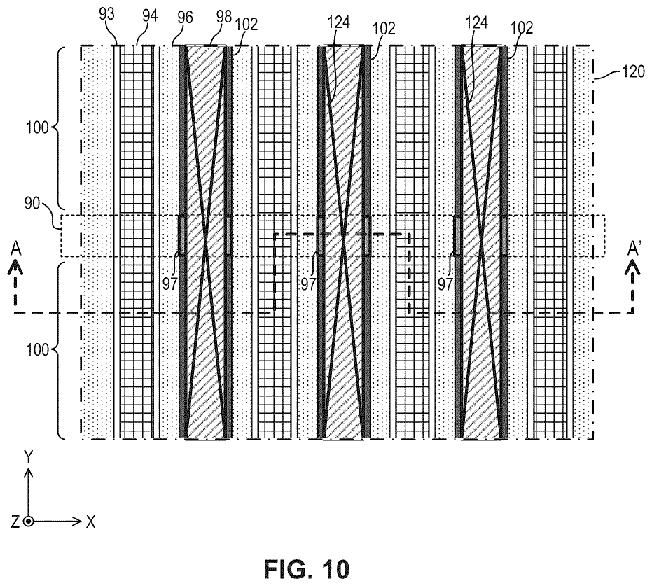

FIG. 10 is a top view of the trench MOSFET device of the present invention illustrating a portion of the trench transistor array in some embodiments. For example, FIG. 10 illustrates the trench MOSFET device 80 of FIGS. 8, 9(a) and 9(b) in some examples. Referring to FIG. 10, a portion 120 of the trench MOSFET device 80 includes the trench gate layer 94 and the gate dielectric layer 93 formed in parallel trenches in a cell array area of the semiconductor layer 92. The trench gate layer 94 in the parallel trenches are connected together, such as by additional trench gate portions, contact and metal layers. In the mesa between adjacent trench gate structures, the source region 96 (shown as dotted areas in FIG. 10) is formed in the body region 95 (not shown). Trench source/body contact 98 is formed above the source regions to contact the source and body regions.

The trench MOSFET device 80 includes the first MOSFET section 90 disposed in a given location along the Y-direction of the transistor cell array and the second MOSFET section 100 formed in the remaining cell array area. In particular, in the first MOSFET section 90, the body contact doped region 97 is formed in the body region 95 while in the second MOSFET section 100, the body contact doped region 102 is formed in the body region 95. The source/body contact 98 extends through the source region 96 to make contact with the respective body contact doped region 97 or 102, as denoted by the crossed-box 124. As shown in FIG. 10, the transistor area of the first MOSFET section 90 is smaller than the transistor area of the second MOSFET section 100. In some embodiments, the first MOSFET section 90 has a transistor area that is a fraction of the transistor area of the second MOSFET section 100. In one embodiment, the transistor area of the first MOSFET section 90 is between 5% to 25% of the transistor area of the second MOSFET section 100.

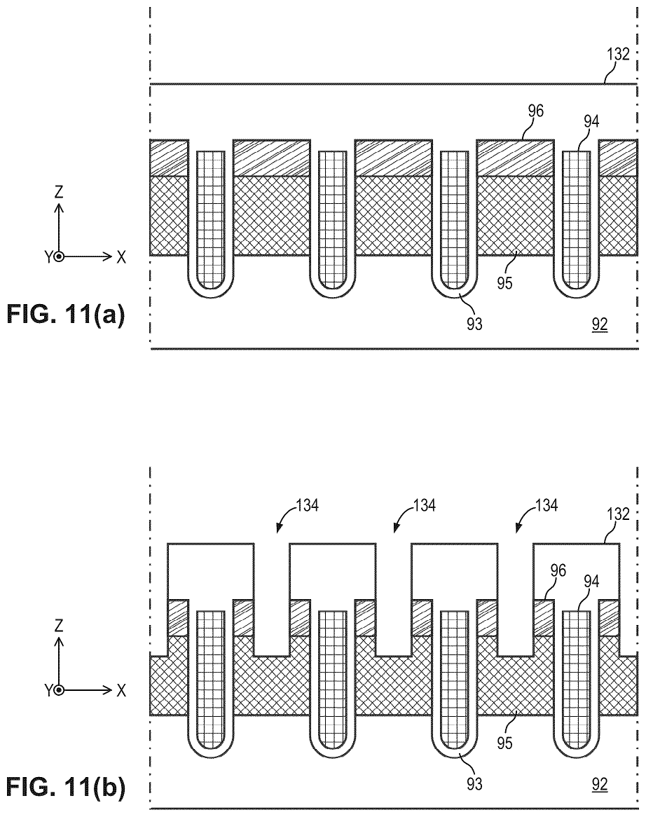

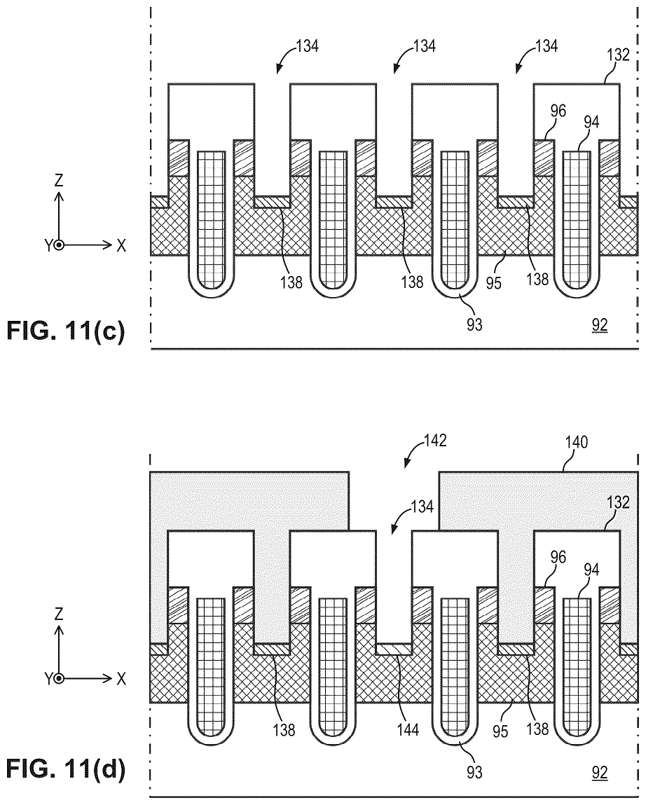

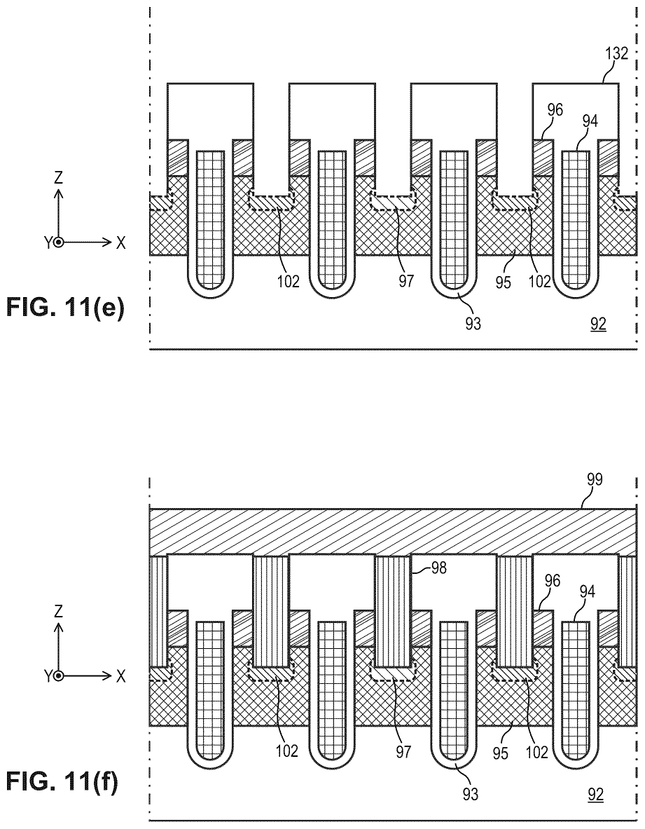

FIGS. 11(a) to 11(f) are cross-sectional views illustrating a fabrication process for forming the trench MOSFET device in alternate embodiments of the present invention. Like elements in FIGS. 8, 9(a), 9(b) and 11(a) to 11(f) are given like reference numbers to simplify the discussion. Furthermore, in the following description, the cross-sectional views shown in FIGS. 11(a) to 11(f) are taken along the line A-A′ in FIG. 10 which traverses the first and second MOSFET sections 90, 100, which are spaced apart in the Y-direction. Taking the cross-sectional view along the line A-A′ allows the NMOS transistors formed in the first MOSFET section and the second MOSFET section to be viewed in the same cross-sectional views.

Referring to FIG. 11(a), the fabrication process starts with forming trenches in a cell array area of a semiconductor layer 92. In the present example, the trench MOSFET device 80 is an NMOS MOSFET device and the semiconductor layer 92 is an N-type semiconductor layer. A gate dielectric layer 93 is formed on the surface of the semiconductor layer 92 and in the trenches, for example, by either a chemical vapor deposition (CVD) process or by thermally grown. In one embodiment, the gate dielectric layer 93 is a silicon dioxide layer (SiO₂) and the gate dielectric layer 93 is also referred to as a gate oxide layer. A conductive gate layer 94 is then formed in the trenches. In some embodiments, the conductive gate layer 94 is a doped polysilicon layer. The doped polysilicon layer may be conformally deposited over the semiconductor layer 92 and the as-deposited doped polysilicon layer is etched back so that only the polysilicon layer in the trenches remains, forming the conductive gate layer 94. In some examples, the polysilicon layer can be deposited using a CVD process and etched back using a wet etch or a dry etch process. At this stage, the fabrication process has completed the trench gate structure formation for the trench MOSFET device. The fabrication process continues with applying the body implant to form the body region 95 in the mesa of the semiconductor layer 92 between the trench gate structures. For example, the body implant may be a lightly doped P-type implant. A body anneal process for the body implant is performed to anneal and diffuse the implanted dopants, forming the body region 95. The anneal process may be performed in a non-reactive ambient at a high temperature, for example.

After the body anneal process, the fabrication process continues with applying the source implant to form the source region 96 in the mesa of the semiconductor layer 92 between the trench gate structures. For example, the source implant may be a heavily doped N-type implant. A source anneal process for the source implant is performed to anneal and diffuse the implanted dopants, forming the source region 96 in the trench MOSFET device. The anneal process may be performed in a non-reactive ambient at a high temperature, for example. After the source anneal process, the trench MOSFET device is encapsulated by a dielectric layer 132. In the present embodiment, the dielectric layer 132 may be a low-temperature oxide layer (LTO) or a combination of LTO and a borophosphosilicate glass (BPSG) layer. The dielectric layer 132 can be deposited using CVD processes, for example. After the BPSG deposition, the semiconductor structure can be planarized, as shown in FIG. 11(a).

Referring to FIG. 11(b), a first contact mask (not shown) is applied to define openings to be made in the dielectric layer 132 and the semiconductor layer 92. A contact etch process, such as an anisotropic dry etch process, is then carried out using the first contact mask to etch the dielectric layer 132 and the semiconductor layer 92 through the source region 96 and into the body region 95 to form body contact openings 134, as shown in FIG. 11(b). Trench source/body contacts are to be formed in the body contact openings 134. The contact openings 134 extends in the Y-direction along the length of the trench gate structures.

Referring to FIG. 11(c), a first body contact implant 138 is applied to dope the bottom portion of the body contact openings 134. For example, the body contact implant 138 may be a low-dose P-type implant. In one example, the body contact implant 138 uses boron as the P-type dopant and has an implant dose of 5×10¹³/cm². Referring to FIG. 11(d), a second contact mask 140 is applied to the semiconductor layer 92 over the dielectric layer 132. The second contact mask 140 defines locations at which the first MOSFET section is to be formed. In particular, the second contact mask 140 defines an opening 142 that extends in the X-direction, orthogonal to the contact openings 134 which extends in the Y-direction. In this manner, the opening 142 (X-direction) is formed self-aligned to the openings 134 (Y-direction) formed in the dielectric layer 132. In particular, the opening 142 exposes a part of the body contact openings 134.

Using the opening 142 defined by the second contact mask 140, which exposes a part of the body contact openings 134, a second body contact implant is applied to introduce additional body contact dopants to the bottom portion of the exposed body contact opening 136, as shown in FIG. 11(d). As a result, the body contact opening 136 exposed by the opening 142 receives a total implant dose 144 being the sum of the first body contact implant and the second body contact implant. For example, the second body contact implant may be a P-type implant using boron as the P-type dopant and having an implant dose of 8×10⁴/cm² to 1×10⁵/cm². An anneal process for the first and second body contact implants is performed to anneal and diffuse the implanted dopants, forming the body contact doped regions 102 and 97 in the trench MOSFET device, as shown in FIG. 11(e). The anneal process may be performed in a non-reactive ambient at a high temperature, for example, after the second contact mask 140 is removed. In one example, the body contact doped region 97, as anneal, has a doping level of 5×10¹⁹/c³ to 2×10²⁰/cm³ as compared to the doping level of the body contact region 102, which has a doping level of 1×10¹⁷/cm³ to 1×10¹⁸/cm³. The body region 95 may have a doping level of 5×10¹⁶/cm³ to 2×10¹⁷/cm³.

Subsequently, referring to FIG. 11(f), tungsten plugs 98 are formed in the contact openings 134. For example, the tungsten plugs 98 may include a conductive adhesion layer, such as a titanium (Ti) and/or a titanium nitride (TiN) layer, and then a tungsten filler layer, both deposited by CVD or PVD processes. A conductive layer 99 is then deposited on the semiconductor structure. In one embodiment, the conductive layer 99 is an aluminum layer and may be deposited using a PVD process or evaporation. A metal mask may be applied and the conductive layer 99 is etched using the metal mask to form metal interconnects. At this stage, the fabrication process for forming the trench MOSFET device is completed.

As thus constructed, the tungsten plugs 98 made contact with the source region 96 and the body contact doped region 97 in the first MOSFET section 90 and the tungsten plugs 98 made contact with the source region 96 and the body contact doped region 102 in the second MOSFET section 100. In this manner, the NMOS transistor formed in the second MOSFET section 100 has a higher body contact resistance than that of the NMOS transistor formed in the first MOSFET section 90, which has a more heavily doped body contact doped region 97 and therefore lower body contact resistance. However, the device characteristics of the NMOS transistor in the second MOSFET section 100 may be better than those in the first MOSFET section 90, such as having a lower threshold voltage.

The drawings provided herein are idealized representations to illustrate embodiments of the present disclosure and are not meant to be actual views of any particular component, structure, or device. The drawings are not to scale, and the sizes and relative sizes and dimensions of layers and regions may be exaggerated for clarity. Variations from the shapes of the illustrations are to be expected. For example, a region illustrated as a box shape may typically have rough and/or nonlinear features. Sharp angles that are illustrated may be rounded. Like numerals refer to like components throughout.

In the present description, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

In this detailed description, process steps described for one embodiment may be used in a different embodiment, even if the process steps are not expressly described in the different embodiment. When reference is made herein to a method including two or more defined steps, the defined steps can be carried out in any order or simultaneously, except where the context dictates or specific instruction otherwise are provided herein. Further, unless the context dictates or express instructions otherwise are provided, the method can also include one or more other steps carried out before any of the defined steps, between two of the defined steps, or after all the defined steps.

In this detailed description, various embodiments or examples of the present invention may be implemented in numerous ways, including as a process; an apparatus; a system; and a composition of matter. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims and the invention encompasses numerous alternatives, modifications, and equivalents. Numerous specific details are set forth in the description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. A trench MOSFET device having a first current terminal, a second current terminal and a gate terminal, the trench MOSFET device comprising:
a trench gate structure formed in a trench in a semiconductor layer of a first conductivity type, the trench gate structure including a conductive gate layer formed in the trench and isolated from the semiconductor layer by a gate dielectric layer, the conductive gate layer forming the gate terminal;
a body region of a second conductivity type in and at a first surface of the semiconductor layer adjacent the trench;
a first doped region of the first conductivity type formed in the body region and at the first surface of the semiconductor layer adjacent the trench, the first doped region forming the first current terminal, wherein the semiconductor layer forms the second current terminal; and
a first body contact doped region of the second conductivity type formed in a first portion of the body region and spaced apart from the first doped region and spaced apart from the trench, the first body contact doped region being more heavily doped than the body region,
wherein the trench MOSFET device comprises a first MOSFET section formed in the first portion of the body region and a second MOSFET section formed outside of the first portion of the body region, the first MOSFET section having a body contact resistance lower than a body contact resistance of the second MOSFET section.

2. The trench MOSFET device of claim 1, further comprising:
a conductive body contact formed in an insolation layer formed over the semiconductor layer, the body contact contacting the first doped region at the first surface of the semiconductor layer in areas of the body region outside of the first portion; and the body contact extending through the first doped region to be in contact with the first doped region and the first body contact doped region formed in the first portion of the body region; and
a conductive layer formed above the isolation layer and in contact with the body contact,
wherein the first MOSFET section includes the body contact contacting the first doped region and the first body contact doped region, and the second MOSFET section includes the body contact contacting the first doped region only.

3. The trench MOSFET device of claim 1, wherein the length of the trench extends in a first direction in the semiconductor layer and a width of the trench extends in a second direction, the second direction being orthogonal to the first direction and in the same plane as the first surface of the semiconductor layer, the length of the trench being larger than the width, and wherein the body region formed in the semiconductor layer adjacent the trench extends in the first direction and the first portion of the body region comprises a portion of the body region positioned in the first direction.

4. The trench MOSFET device of claim 1, wherein the first MOSFET section and the second MOSFET section form MOS transistors that are connected in parallel, wherein the first doped region forms the first current terminals of the first and second MOSFET sections, the semiconductor layer forms the second current terminals of the first and second MOSFET sections, and the conductive gate layer forms the gate terminals of the first and second MOSFET sections.

5. The trench MOSFET device of claim 1, wherein the first MOSFET section has a first transistor area and the second MOSFET section has a second transistor area, the first transistor area being a fraction of the second transistor area.

6. The trench MOSFET device of claim 5, wherein the first transistor area is between 5% to 25% of the second transistor area.

7. The trench MOSFET device of claim 1, wherein the first MOSFET section has a first threshold voltage and the second MOSFET section has a second threshold voltage, the first threshold voltage being greater than the second threshold voltage.

8. The trench MOSFET device of claim 1, wherein the trench MOSFET device comprises an array of trench transistor cells defined by trench gate structures and associated body regions and first doped regions formed in the semiconductor layer between adjacent pair of trench gate structures, the first MOSFET section including trench transistor cells formed in the first portion of the body regions including the first body contact doped region, and the second MOSFET section including trench transistor cells formed outside of the first portion of the body regions.

9. The trench MOSFET device of claim 1, further comprising:
a second body contact doped region of the second conductivity type formed in the body region outside of the first portion, the second body contact doped region being spaced apart from the first doped region and spaced apart from the trench, the second body contact doped region being more heavily doped than the body region and more lightly doped than the first body contact doped region.

10. The trench MOSFET device of claim 9, further comprising:
a conductive body contact formed in an insolation layer formed over the semiconductor layer, the body contact extending through the first doped region to be in contact with the first doped region and the first body contact doped region formed in the first portion of the body region and the body contact extending through the first doped region to be in contact with the first doped region and the second body contact doped region formed in the body region outside of the first portion; and
a conductive layer formed above the isolation layer and in contact with the body contact,
wherein the first MOSFET section includes the body contact contacting the first doped region and the first body contact doped region, and the second MOSFET section includes the body contact contacting the first doped region and the second body contact doped region.

11. The trench MOSFET device of claim 9, wherein the length of the trench extends in a first direction in the semiconductor layer and a width of the trench extends in a second direction, the second direction being orthogonal to the first direction and in the same plane as the first surface of the semiconductor layer, the length of the trench being larger than the width, and wherein the body region formed in the semiconductor layer adjacent the trench extends in the first direction and the first portion of the body region comprises a portion of the body region positioned in the first direction.

12. The trench MOSFET device of claim 9, wherein the first MOSFET section has a first transistor area and the second MOSFET section has a second transistor area, the first transistor area being a fraction of the second transistor area.

13. The trench MOSFET device of claim 12, wherein the first transistor area is between 5% to 25% of the second transistor area.

14. The trench MOSFET device of claim 9, wherein the first MOSFET section has a first threshold voltage and the second MOSFET section has a second threshold voltage, the first threshold voltage being greater than the second threshold voltage.

15. The trench MOSFET device of claim 9, wherein the trench MOSFET device comprises an array of trench transistor cells defined by trench gate structures and associated body regions and first doped regions formed in the semiconductor layer between adjacent pair of trench gate structures, the first MOSFET section including trench transistor cells formed in the first portion of the body regions including the first body contact doped region, and the second MOSFET section including trench transistor cells formed outside of the first portion of the body regions.

16. A method for forming a trench MOSFET device, comprising:
providing a semiconductor layer of a first conductivity type;
forming an array of trench transistor cells in the semiconductor layer, comprising forming the trench transistor cells being defined by trench gate structures;
forming body regions of a second conductivity type in the array of trench transistor cells;
forming source regions of the first conductivity type in the body regions of the array of trench transistor cells;
forming a first body contact doped region of the second conductivity type in each body region in a first portion of the array of trench transistor cells, the first body contact doped region being spaced apart from the source region formed in the respective body region and spaced apart from the trench gate structure, the first body contact doped region being more heavily doped than the body region;
forming a body contact to the first body contact doped region in the first portion of the body regions and to the source regions only outside of the first portion of the body regions; and
forming a first conductive layer in contact with the body contact.

17. The method of claim 16, wherein forming the trench transistor cells being defined by trench gate structures comprises:
forming a conductive gate layer in trenches formed in the semiconductor layer, the conductive gate layer being isolated from the semiconductor layer by a gate dielectric layer in each trench.

18. The method of claim 16, wherein a first MOSFET section is formed in the first portion of the array of trench transistor cells and a second MOSFET section is formed outside of the first portion, the first MOSFET section having a body contact resistance lower than a body contact resistance of the second MOSFET section.

19. The method of claim 16, wherein the first MOSFET section has a first transistor area and the second MOSFET section has a second transistor area, the first transistor area being a fraction of the second transistor area.

20. The method of claim 16, further comprising:
forming a second body contact doped region of the second conductivity type in each body region outside of the first portion, the second body contact doped region being spaced apart from the source region formed in the respective body region and spaced apart from the trench gate structure, the second body contact doped region being more heavily doped than the body region and more lightly doped than the first body contact doped region; and
forming the body contact to the first body contact doped region in the first portion of the trench transistor cells and to the second body contact doped region outside of the first portion.
